(19) United States
(12) Patent Application Publication
(10) Pub. No.: US 2023/0298868 A1
(43) Pub. Date: Sep. 21, 2023

(54) PLASMA TREATMENT APPARATUS AND PLASMA TREATMENT METHOD

(71) Applicant: KIOXIA CORPORATION, Tokyo (JP)

(72) Inventor: Yusuke KONDO, Yokkaichi Mie (JP)

(21) Appl. No.: 17/898,168

(22) Filed: Aug. 29, 2022

(30) Foreign Application Priority Data
Mar. 18, 2022 (JP) 2022-043837

(51) Int. Cl. H01J 37/32; H01L 21/311

(52) U.S. Cl. CPC H01J 37/32724; H01J 37/32449; H01L 21/31116; H01J 2237/002; H01J 2237/2007; H01J 2237/24585; H01J 2237/182; H01J 37/32816; H01J 2237/3341

(57) ABSTRACT

According to one embodiment, a plasma treatment apparatus includes a substrate holder that holds a semiconductor substrate, a gas supply unit that supplies a mixed gas to a gas supply space formed between the semiconductor substrate and the substrate holder, a flow rate adjustment unit that adjusts a flow rate of different gases in the mixed gas, and a flow rate control unit. The mixed gas contains, for example, helium and argon, and the flow rate control that controls the flow rate adjustment unit to change the relative flow rates of helium and argon, or the like, to control a temperature of the substrate.

### CROSS-REFERENCE TO RELATED APPLICATION

This application is based upon and claims the benefit of priority from Japanese Patent Application No. 2022-043837, filed Mar. 18, 2022, the entire contents of which are incorporated herein by reference.

### FIELD

Embodiments described herein relate generally to a plasma treatment apparatus and a plasma treatment method.

### BACKGROUND

A plasma dry etching apparatus is known as one of type plasma treatment apparatus. This etching apparatus includes a substrate holder that holds a substrate, such as a semiconductor substrate, and controls the temperature of the substrate by using a helium gas and/or a refrigerant supplied at the back side of the substrate.

### BRIEF DESCRIPTION OF THE DRAWINGS

FIG. 1 is a block diagram showing a schematic configuration of a plasma treatment apparatus of a first embodiment.

FIG. 2 is a flowchart showing a procedure of treatment executed by a control unit of the first embodiment.

FIG. 3 is a block diagram showing a schematic configuration of a plasma treatment apparatus of a second embodiment.

FIG. 4 is a timing chart showing a transition of the temperature of a semiconductor substrate in a plasma treatment apparatus of a Comparative Example.

FIG. 5 is a timing chart showing a transition of the temperature of a semiconductor substrate in the plasma treatment apparatus of a second embodiment.

FIG. 6 is a block diagram showing a schematic configuration of a plasma treatment apparatus of a third embodiment.

FIG. 7 is a block diagram showing a schematic configuration of a plasma treatment apparatus of a first modification example of a third embodiment.

FIG. 8 is a block diagram showing a schematic configuration of a plasma treatment apparatus of a second modification example of a third embodiment.

FIG. 9 is a cross-sectional view showing a cross-sectional structure taken along line IX-IX of FIG. 8.

### DETAILED DESCRIPTION

Embodiments provide a plasma treatment apparatus and a plasma treatment method capable of improving the controllability of a substrate temperature during processing.

In general, according to one embodiment, a plasma treatment apparatus includes a holding unit configured to hold a substrate during a plasma treatment process. A gas supply unit is configured to supply a mixed gas, including a first gas and a second gas, to a gas supply space formed between the substrate and the holding unit. A flow rate adjustment unit is configured to change a flow rate of each of the first and second gases. A flow rate control unit is configured to control the flow rate adjustment unit during the plasma treatment process to change a relative flow rate of the first and second gases to control a temperature of the substrate.

Hereinafter, certain example embodiments of a plasma treatment apparatus and a plasma treatment method will be described with reference to the drawings. The same or substantially similar components, elements, or aspects will generally be given the same reference numerals in the drawings, and duplicate description thereof will be omitted.

### First Embodiment

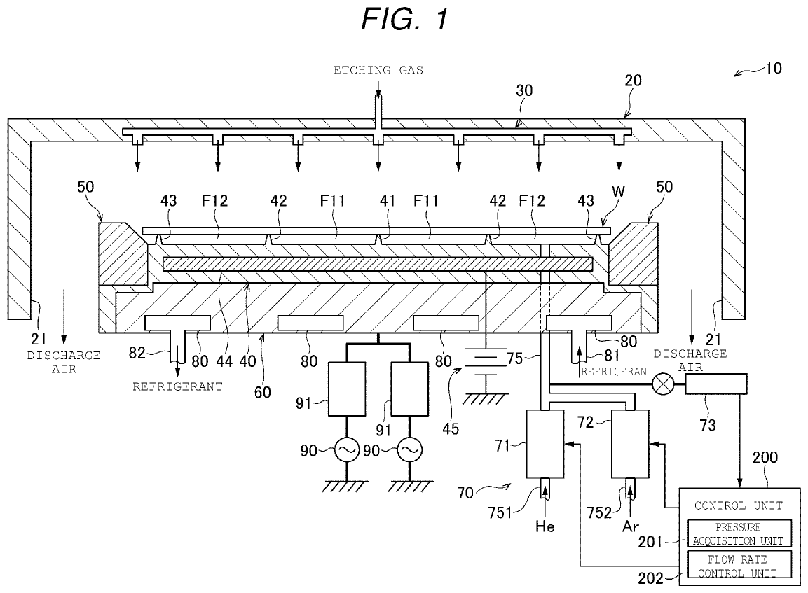

A plasma treatment apparatus 10 of this first embodiment shown in FIG. 1 is a so-called plasma dry etching apparatus that etches a semiconductor substrate on which a film to be processed has been formed. The plasma treatment apparatus uses a reactive ion etching (RIE) method or the like. The plasma treatment apparatus 10 is not limited to a plasma dry etching apparatus, and in other examples may be another type of plasma treatment apparatus such as plasma chemical vapor deposition (CVD) apparatus. The plasma treatment apparatus 10 includes a chamber 20, a shower head 30, a substrate holder 40, an edge ring 50, a plasma electrode 60, and a gas supply unit 70.

The chamber 20 is a box-shaped member that forms a space for accommodating a semiconductor substrate W. The inside of the chamber 20 can be depressurized and placed in a vacuum state. The semiconductor substrate W may be, for example, a semiconductor wafer such as a silicon wafer, but is not limited to a semiconductor material and may be another type of substrate such as a quartz substrate. On the semiconductor substrate W, a multilayer film including a film to be processed, a circuit pattern formed in the multilayer film, and the like may be provided.

The shower head 30 is provided inside the upper wall portion of the chamber 20. The shower head 30 is formed in a hollow shape. The shower head 30 has multiple holes which are open toward the substrate holder 40, and the etching gas is introduced into the internal space of the chamber 20 through these holes. The chamber 20 is provided with a discharge unit 21. The used etching gas is discharged to the outside through the discharge unit 21.

The substrate holder 40 holds the semiconductor substrate W on a surface thereof. The substrate holder 40 is made of an insulating material such as ceramic. A plurality of support units 41, 42, 43 are provided on the surface of the substrate holder 40. The support unit 41 is a conical protrusion portion provided at the central portion of the substrate holder 40. The support units 42 and 43 are ring-shaped protrusion portions that extend concentrically around the support unit 41. The support unit 43 is provided outside the support unit 42. In this embodiment, the substrate holder 40 corresponds to a holding unit.

An electrode 44 is provided inside the substrate holder 40. A voltage is applied to the electrode 44 from a power source 45. The substrate holder 40 is a so-called electrostatic chuck that attracts the semiconductor substrate W by the Coulomb force generated between the electrode 44 to which the voltage is applied and the semiconductor substrate W, such that the semiconductor substrate W is brought into close contact with the tip portions of the support units 41 to 43. Of the gaps formed between the substrate holder 40 and the semiconductor substrate W, a gap formed between the support unit 41 and the support unit 42 forms a first gas supply space F11, and a gap formed between the support unit 42 and the support unit 43 forms a second gas supply space F12. In this embodiment, the first gas supply space F11 and the second gas supply space F12 communicate with (fluidly connect to) each other. Gas is supplied to the gas supply spaces F11 and F12 from the gas supply unit 70.

The edge ring 50 is provided around the substrate holder 40. The edge ring 50 is an annular member integrally assembled with the substrate holder 40. The edge ring 50 prevents the positional deviation of the semiconductor substrate W.

The plasma electrode 60 is provided inside or at the bottom of the substrate holder 40. A high frequency power source 90 and a matching circuit 91 are connected to the plasma electrode 60. The high frequency power source 90 applies a high frequency voltage to the plasma electrode 60. The matching circuit 91 is provided between the plasma electrode 60 and the high frequency power source 90.

In the plasma treatment apparatus 10, the shower head 30 is electrically grounded. Therefore, a high frequency voltage is applied between the plasma electrode 60 and the shower head 30. Due to this high frequency voltage, the etching gas supplied from the shower head 30 into the chamber 20 enters a plasma state, and the surface of the semiconductor substrate W is etched in the generated plasma atmosphere. The matching circuit 91 is provided to match the high frequency power source 90 with the impedance of the plasma and prevent the reflection of electric power.

A refrigerant flow path 80 is formed inside the plasma electrode 60. An inflow path 81 is connected to the upstream part of the refrigerant flow path 80. An outflow path 82 is connected to the downstream part of the refrigerant flow path 80. The inflow path 81 and the outflow path 82 are connected to a refrigerant circulation device (e.g., a chiller). The refrigerant cooled in the refrigerant circulation device flows into the refrigerant flow path 80 through the inflow path 81. The refrigerant that flowed through the refrigerant flow path 80 flows back into the refrigerant circulation device through the outflow path 82 to be cooled again. During the plasma treatment, the refrigerant flowing through the refrigerant flow path 80 cools the plasma electrode 60 which otherwise heats during use, the temperature of the plasma electrode 60 can thus be controlled. Furthermore, the refrigerant flowing through the refrigerant flow path 80 also functions to cool the semiconductor substrate W via gas flow through the plasma electrode 60 and the substrate holder 40, into gas supply spaces F11 and F12. Thus, the temperature of the semiconductor substrate W is also controlled during processing. The refrigerant may be, for example, a gas such as nitrogen or fluorine, or a liquid such as water or an ionic liquid.

The gas supply unit 70 supplies gas to the gas supply spaces F11 and F12 formed between the substrate holder 40 and the semiconductor substrate W through a gas supply path 75. The gas supply unit 70 has flow rate adjustment units 71 and 72 and a pressure gauge 73.

The upstream part of the gas supply path 75 has two flow paths (751 and 752) which merge together. A helium (He) gas is supplied to the first branch flow path 751 at a predetermined pressure. A gas having a thermal conductivity lower than that of the helium gas, such as an argon (Ar) gas, a neon (Ne) gas, or a freon gas, is supplied to the second branch flow path 752 at a predetermined pressure. Hereinafter, a case where an argon gas is supplied to the second branch flow path 752 will be described as an example.

A helium gas is supplied to the gas supply path 75 from the first branch flow path 751, and an argon gas is supplied from the second branch flow path 752. Therefore, a mixed gas of helium and argon flows in the gas supply path 75. The mixed gas is supplied to the gas supply spaces F11 and F12 formed between the substrate holder 40 and the semiconductor substrate W through the gas supply path 75. Therefore, the mixed gas is supplied to the bottom surface of the semiconductor substrate W as a so-called backside gas.

The flow rate adjustment unit 71 is provided in the first branch flow path 751. The flow rate adjustment unit 71 adjusts the flow rate of the helium gas flowing from the first branch flow path 751 to the gas supply path 75. The flow rate adjustment unit 72 is provided in the second branch flow path 752. The flow rate adjustment unit 72 adjusts the flow rate of the argon gas flowing from the second branch flow path 752 to the gas supply path 75. The flow rate adjustment units 71 and 72 may be mass flow controllers, control valves, or the like.

The pressure gauge 73 is provided in the gas supply path 75. The pressure gauge 73 measures the pressure of the mixed gas flowing through the gas supply path 75, and outputs a signal corresponding to the measured pressure to a control unit 200.

The plasma treatment apparatus 10 includes the control unit 200 for controlling processes of the plasma treatment apparatus 10. The control unit 200 controls, for example, the flow rate adjustment units 71 and 72. The control unit 200 can be a microcomputer having a CPU, a storage device, and the like. The control unit 200 includes a pressure acquisition unit 201 and a flow rate control unit 202 as functional aspects implemented by the CPU executing a program stored in the storage device.

The pressure acquisition unit 201 acquires information on the pressure of the mixed gas flowing through the gas supply path 75 based on the output signal of the pressure gauge 73, that is, the pressure of the mixed gas supplied to the gas supply spaces F11 and F12.

The flow rate control unit 202 controls the flow rate adjustment units 71 and 72 to execute a control for maintaining the pressure of the mixed gas at a predetermined pressure and a control for changing the flow rate ratio of the helium gas and the argon gas contained in the mixed gas.

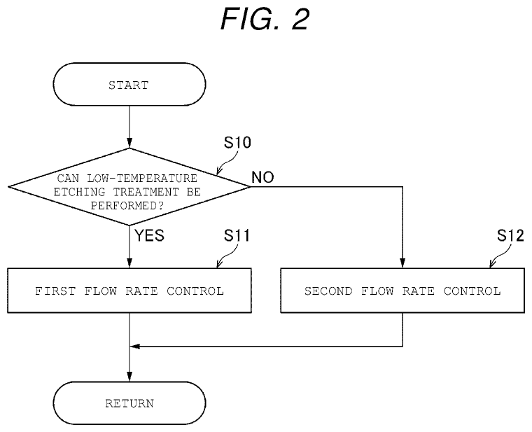

Next, a specific procedure of the control executed by the flow rate control unit 202 will be described with reference to FIG. 2. In addition, the process shown in FIG. 2 is repeatedly executed in the plasma atmosphere at a predetermined cycle during a period in which the semiconductor substrate W is being subjected to plasma treatment such as dry etching.

As shown in FIG. 2, the flow rate control unit 202 first determines whether or not a low-temperature etching treatment, such as cryogenic etching, can be performed (step S10).

For example, in the manufacturing process of a NAND flash memory, plasma dry etching treatment may be used when forming holes such as memory holes or contact holes on the semiconductor substrate W. In the hole forming process, for example, when forming holes in the film to be processed on the semiconductor substrate W, it is necessary to etch portions of the film deeply. In such a case, it is desirable that the temperature of the semiconductor substrate W be lower. On the other hand, in a process of finely adjusting the shape and size of the hole after forming the hole on the semiconductor substrate W, it is necessary to process the semiconductor substrate W less substantially. In such a case, it is desirable that the temperature of the semiconductor substrate W be higher.

In this manner, when processing the semiconductor substrate W, it may be more effective to use low-temperature etching treatment or high-temperature etching treatment depending on the specific nature of the intended processing. In this embodiment, the required execution time and the execution period for the low-temperature etching treatment and the high-temperature etching treatment are mapped and stored in the storage device of the control unit 200. After starting the etching treatment, the flow rate control unit 202 determines whether or not the low-temperature etching treatment can be (or is to be) performed based on the map stored in the control unit 200.

When the flow rate control unit 202 determines that the low-temperature etching treatment can be performed (step S10: YES), the flow rate control unit 202 executes the first flow rate control (step S11). Specifically, as the first flow rate control, the flow rate control unit 202 controls the flow rate adjustment units 71 and 72 such that the flow rate of the helium gas contained in the mixed gas becomes larger than the flow rate of the argon gas while still maintaining the pressure of the mixed gas at a predetermined pressure. For example, the flow rate control unit 202 controls the flow rate adjustment units 71 and 72 such that the flow rate of each of the helium gas and the argon gas contained in the mixed gas is 10:0 (helium gas flow rate:argon gas flow rate). By increasing the flow rate ratio of the helium gas contained in the mixed gas in this manner, the thermal conductivity of the mixed gas (through, the mixture is substantially helium only at this time, it will still be referred to as the mixed gas) increases, such that the heat of the semiconductor substrate W is more easily absorbed by the refrigerant via the mixed gas. In other words, the actual temperature of the semiconductor substrate W can be lowered. For example, when the temperature of the refrigerant is −20° C., the process temperature for the semiconductor substrate W can be set to approximately 0° C. In this embodiment, the helium gas corresponds to a first gas and the argon gas corresponds to a second gas.

On the other hand, when the flow rate control unit 202 makes a negative determination in step S10 (step S10: NO), that is, when the flow rate control unit 202 determines that the high-temperature etching treatment can be (or is to be) performed, the flow rate control unit 202 executes the second flow rate control (step S12). Specifically, the flow rate control unit 202 controls the flow rate adjustment units 71 and 72 such that the flow rate of the helium gas contained in the mixed gas becomes smaller than the flow rate of the argon gas while maintaining the pressure of the mixed gas at a predetermined pressure. For example, the flow rate control unit 202 controls the flow rate adjustment units 71 and 72 such that the flow rate of each of the helium gas and the argon gas contained in the mixed gas is 1:9 (helium gas flow rate:argon gas flow rate). By increasing the flow rate ratio of the argon gas contained in the mixed gas in this manner, the thermal conductivity of the mixed gas decreases, such that it is more difficult for the heat of the semiconductor substrate W to be absorbed by the refrigerant via the mixed gas. Therefore, the actual temperature of the semiconductor substrate W can be raised. For example, when the temperature of the refrigerant is −20° C., the process temperature for the semiconductor substrate W can be set to approximately 80° C.

As described above, in the control executed by the flow rate control unit 202, the process shown in FIG. 2 is repeatedly executed. Therefore, the flow rate control unit 202 may execute both the first flow rate control and the second flow rate control.

As described above, the plasma treatment apparatus 10 of this embodiment includes the substrate holder 40, the gas supply unit 70, the flow rate adjustment units 71 and 72, and the flow rate control unit 202. The substrate holder 40 holds the semiconductor substrate W. The gas supply unit 70 supplies a mixed gas containing two types of gases having different thermal conductivities, helium gas and argon gas, to the gas supply spaces F11 and F12. The flow rate adjustment units 71 and 72 adjust the flow rate of each of the helium gas and the argon gas contained in the mixed gas. The flow rate control unit 202 executes a first flow rate control for making the flow rate of the helium gas larger than the flow rate of the argon gas and a second flow rate control for making the flow rate of the argon gas larger than the flow rate of the helium gas. According to this configuration, the thermal conductivity of the mixed gas can be changed, and as a result, control of the temperature of the semiconductor substrate W can be improved.

As a method of changing the temperature of the semiconductor substrate W, a method of changing the temperature of the refrigerant may be considered. However, generally, it takes a considerable amount of time for the temperature of the semiconductor substrate W to actually change after changing the temperature of the refrigerant, such that there is a concern that the temperature responsiveness for control of the semiconductor substrate W will be low. In this regard, when the thermal conductivity of the mixed gas is changed as in this embodiment, the temperature of the semiconductor substrate W can be changed quickly, and thus the temperature responsiveness for control of the semiconductor substrate W can be improved.

Furthermore, as a comparative example, when just a single gas (such as helium) is used as the backside gas for the semiconductor substrate W, it is also possible to change the temperature of the semiconductor substrate W by changing the pressure of the supplied helium gas. However, when a mixed gas is used as the backside gas of the semiconductor substrate W as in this embodiment, the possible range of change in the thermal conductivity of the backside gas can be increased. As a result, since it is possible to increase the range of change in the temperature of the semiconductor substrate W, it is possible to improve the manufacturability of the semiconductor substrate W, and it is possible to more suitably manufacture the semiconductor device.

### Second Embodiment

Next, a second embodiment of the plasma treatment apparatus 10 and the plasma treatment method will be described. Hereinafter, the differences from the plasma treatment apparatus 10 and the plasma treatment method of the first embodiment will be mainly described.

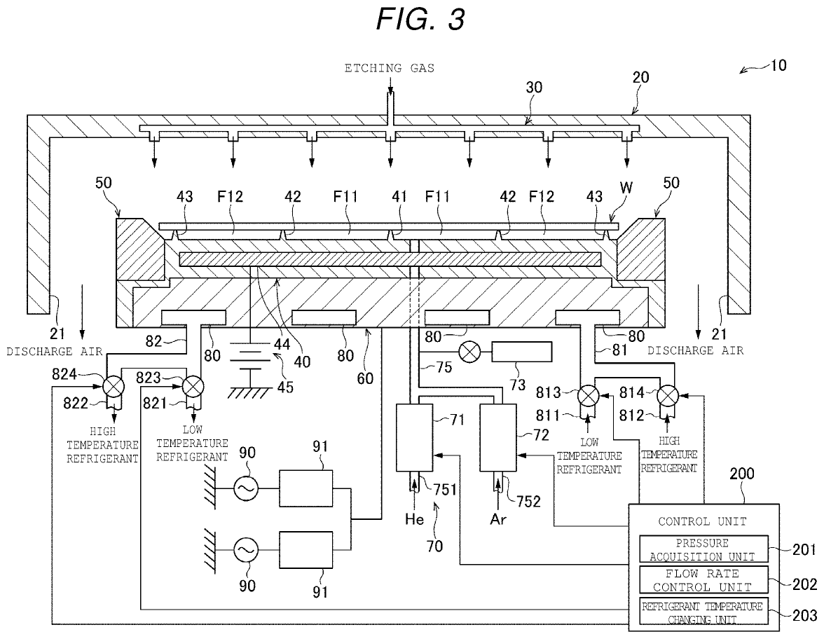

As shown in FIG. 3, in the plasma treatment apparatus 10 of this second embodiment, the upstream part of the inflow path 81 of the refrigerant has two paths (811 and 812) which merge together. The downstream part of the outflow path 82 of the refrigerant is branched into two flow paths 821 and 822. The first inflow side branch flow path 811 and the second outflow side branch flow path 821 are connected to a first refrigerant circulation device. The second inflow side branch flow path 812 and the second outflow side branch flow path 822 are connected to a second refrigerant circulation device. The temperature of the refrigerant supplied from the second refrigerant circulation device to the second inflow side branch flow path 812 is higher than the temperature of the refrigerant supplied from the first refrigerant circulation device to the first inflow side branch flow path 811. Hereinafter, the refrigerant supplied from the first refrigerant circulation device to the first inflow side branch flow path 811 is referred to as a “low temperature refrigerant”, and the refrigerant supplied from the second refrigerant circulation device to the second inflow side branch flow path 812 is referred to as a “high temperature refrigerant”. In this embodiment, the temperature of the low temperature refrigerant is set to 10° C. and the temperature of the high temperature refrigerant is set to 60° C.

The branch flow paths 811, 812, 821, and 822 are provided with valves 813, 814, 823, and 824, respectively. The valves 813, 814, 823, and 824 open and close the branch flow paths 811, 812, 821, and 822, respectively.

The control unit 200 further includes a refrigerant temperature changing unit 203 as a functional aspect implemented by the CPU executing a program stored in the storage device. The refrigerant temperature changing unit 203 changes the temperature of the refrigerant supplied to the refrigerant flow path 80 by controlling the state of the valves 813, 814, 823, and 824.

Specifically, the refrigerant temperature changing unit 203 opens the valves 813 and 823 and closes the valves 814 and 824 when the temperature of the refrigerant flowing through the refrigerant flow path 80 is to be lowered. As a result, the low temperature refrigerant cooled by the first refrigerant circulation device is supplied to the refrigerant flow path 80, and thus the low temperature refrigerant flows inside the plasma electrode 60. As a result, the heat of the semiconductor substrate W is more easily absorbed by the refrigerant, and thus the temperature of the semiconductor substrate W can be further lowered.

In addition, the refrigerant temperature changing unit 203 closes the valves 813 and 823 and opens the valves 814 and 824 when the temperature of the refrigerant flowing through the refrigerant flow path 80 is to be raised. As a result, the high temperature refrigerant cooled by the second refrigerant circulation device is supplied to the refrigerant flow path 80, and thus the high temperature refrigerant flows inside the plasma electrode 60. As a result, it is more difficult for the heat of the semiconductor substrate W to be absorbed by the refrigerant, and thus the temperature of the semiconductor substrate W can be further raised.

As described above, the plasma treatment apparatus 10 of this second embodiment includes the refrigerant temperature changing unit 203 that changes the temperature of the refrigerant supplied to the substrate holder 40. By combining the configuration for changing the temperature of the refrigerant and the configuration for adjusting the flow rate of each of the helium gas and the argon gas contained in the mixed gas, it is possible to change the temperature of the semiconductor substrate W more flexibly.

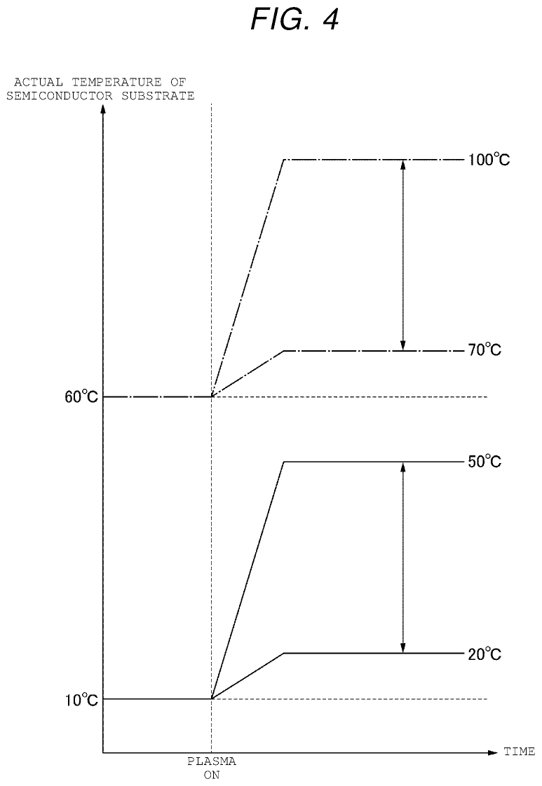

For example, as a comparative example, when a single gas (helium) is used as the backside gas of the semiconductor substrate W, it is possible to change the temperature of the semiconductor substrate W by changing the pressure of the helium gas as shown in FIG. 4. In other words, when the pressure of the helium gas is changed while the low temperature refrigerant of 10° C. is flowing through the refrigerant flow path 80, it is possible to change the temperature of the semiconductor substrate W in the range of 20° C. to 50° C. as shown by the solid line in FIG. 4. In addition, when the pressure of the helium gas is changed while the high temperature refrigerant of 60° C. is flowing through the refrigerant flow path 80, it is possible to change the temperature of the semiconductor substrate W in the range of 70° C. to 100° C. as shown by the one-dot chain line in FIG. 4.

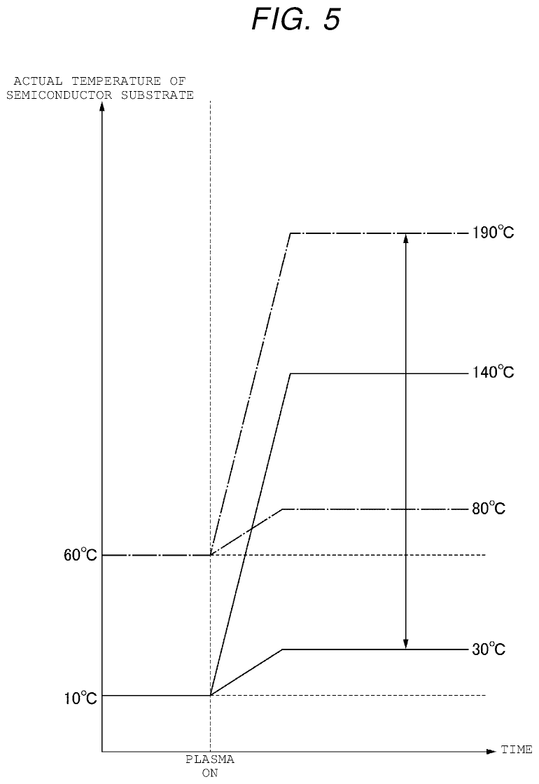

On the other hand, when a mixed gas of a helium gas and an argon gas is used as the backside gas as in this second embodiment, by changing the flow rate ratio of the helium gas and the argon gas while maintaining the pressure of the mixed gas constant, it is possible to change the temperature of the semiconductor substrate W as shown in FIG. 5. In other words, when the flow rate ratio of the helium gas and the argon gas is changed while the low temperature refrigerant of 10° C. is flowing through the refrigerant flow path 80, it is possible to change the temperature of the semiconductor substrate W in the range of 30° C. to 140° C. as shown by the solid line in FIG. 5. Furthermore, when the flow rate ratio of the helium gas and the argon gas is changed while the high temperature refrigerant of 60° C. is flowing through the refrigerant flow path 80, it is possible to change the temperature of the semiconductor substrate W in the range of 80° C. to 190° C. as shown by the one-dot chain line in FIG. 5. As a result, by using the plasma treatment apparatus of this second embodiment, it is possible to change the temperature of the semiconductor substrate W in the range of 30° C. to 190° C.

In this manner, by combining the configuration for changing the temperature of the refrigerant and the configuration for adjusting the flow rate of each of the helium gas and the argon gas contained in the mixed gas, it is possible to change the temperature of the semiconductor substrate W more flexibly over a wider range.

Furthermore, the plasma treatment apparatus 10 of this embodiment includes the branch flow paths 811, 812, 821, and 822 for a refrigerant supply unit that supplies two types of refrigerants having different temperatures to the substrate holder 40. The plasma treatment apparatus 10 includes the valves 813, 814, 823, and 824 for a switching unit that individually switches on and off or otherwise adjusts a flow of the two types of the refrigerants having different temperatures that are supplied to the substrate holder 40. The refrigerant temperature changing unit 203 changes the temperature of the refrigerant supplied to the substrate holder 40 by controlling the valves 813, 814, 823, and 824. According to this configuration, it is possible to provide a configuration in which the temperature of the refrigerant supplied to the substrate holder 40 can be changed.

### Third Embodiment

Next, a third embodiment of the plasma treatment apparatus 10 and the plasma treatment method will be described. Hereinafter, the differences from the plasma treatment apparatus 10 and the plasma treatment method of the first embodiment will be mainly described.

When the plasma treatment is performed on the semiconductor substrate W using the plasma treatment apparatus 10 shown in FIG. 1, a temperature distribution is generated in the semiconductor substrate W such that the temperature of the outer peripheral portion will be higher than the temperature of the central portion thereof. For example, the temperature of the outer peripheral portion is approximately 20° C. to 30° C. higher than the temperature of the central portion of the semiconductor substrate W. This is because not just the backside gas is in contact with the outer edge portion of the semiconductor substrate W, such that the temperature tends to rise at this portion. If the temperature distribution of the semiconductor substrate W becomes non-uniform in this manner when processing the semiconductor substrate W by the plasma treatment, for example, the size and shape of holes (or other features) are likely to vary. In other words, this case is not preferable because the processing accuracy of the semiconductor substrate W deteriorates.

Therefore, in the plasma treatment apparatus 10 of this third embodiment, the temperature distribution of the semiconductor substrate W is made more uniform by cooling the outer peripheral portion more than the central portion of the semiconductor substrate W.

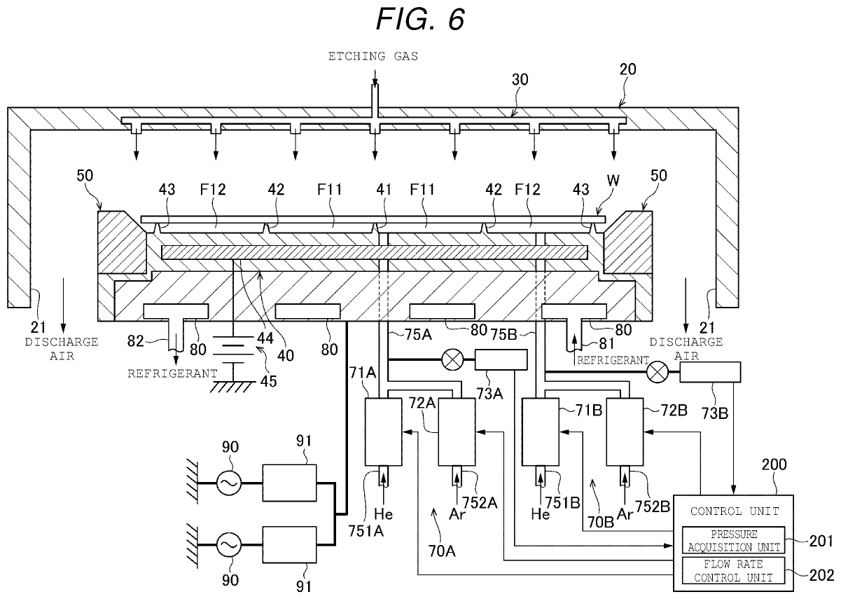

Specifically, as shown in FIG. 6, in the plasma treatment apparatus 10 of this third embodiment, the first gas supply space F11 and the second gas supply space F12 are formed as independent spaces. In this third embodiment, the support units 41 to 43 formed on the surface of the semiconductor substrate W corresponds to a partition unit that partitions the gap formed between the semiconductor substrate W and the substrate holder 40 into the first gas supply space F11 and the second gas supply space F12, which are independent of each other.

The plasma treatment apparatus 10 includes a first gas supply unit 70A that supplies the mixed gas to the first gas supply space F11 and a second gas supply unit 70B that supplies the mixed gas to the second gas supply space F12. Hereinafter, the mixed gas supplied from the first gas supply unit 70A to the first gas supply space F11 is referred to as a “first mixed gas”, and the mixed gas supplied from the second gas supply unit 70B to the second gas supply space F12 is referred to as a “second mixed gas”.

Since the configurations of each of the first gas supply unit 70A and the second gas supply unit 70B are the same as the configuration of the gas supply unit 70 of the first embodiment shown in FIG. 1, the additional description thereof will be omitted.

In FIG. 6, in order to distinguish the components of the first gas supply unit 70A and the components of the second gas supply unit 70B from each other, “A” is added to the end of the reference numerals for the former's components and “B” is added to the end of the reference numerals for the latter's components.

The flow rate control unit 202 of the control unit 200 controls the flow rate adjustment units 71A and 72A of the first gas supply unit 70A to execute a control for maintaining the pressure of the first mixed gas supplied to the first gas supply space F11 at a predetermined pressure, and a control for changing the flow rate ratio of each of the helium gas and the argon gas contained in the first mixed gas. In addition, the flow rate control unit 202 controls the flow rate adjustment units 71B and 72B of the second gas supply unit 70B to execute a control for maintaining the pressure of the second mixed gas supplied to the second gas supply space F12 at a predetermined pressure, and a control for changing the flow rate ratio of each of the helium gas and the argon gas contained in the second mixed gas.

For example, when the flow rate control unit 202 controls the temperature of the refrigerant flowing through the refrigerant flow path 80 to 20° C. and the temperature of the semiconductor substrate W to 80° C., the flow rate control unit 202 controls the flow rate adjustment units 71A and 72A of the first gas supply unit 70A such that the flow rate of the helium gas contained in the first mixed gas is smaller than the flow rate of the argon gas. For example, the flow rate control unit 202 controls the flow rate adjustment units 71A and 72A such that the flow rate of each of the helium gas and the argon gas contained in the mixed gas is 2.5:7.5 (helium gas flow rate:argon gas flow rate).

In this third embodiment, the flow rate adjustment units 71A and 72A correspond to the first flow rate adjustment unit that adjusts the flow rate of each of the two types of gases contained in the first mixed gas.

The flow rate control unit 202 also controls the flow rate adjustment units 71B and 72B of the second gas supply unit 70B such that the flow rate of the helium gas contained in the second mixed gas becomes larger than the flow rate of the argon gas. For example, when a temperature difference of approximately 20° C. is generated between the central portion and the outer peripheral portion of the semiconductor substrate W, the flow rate control unit 202 controls the flow rate adjustment units 71B and 72B such that the flow rate of each of the helium gas and the argon gas contained in the second mixed gas is 6:4 (helium gas flow rate:argon gas flow rate).

In this third embodiment, the flow rate adjustment units 71B and 72B correspond to the second flow rate adjustment unit that adjusts the flow rate of each of the two types of gases contained in the second mixed gas.

The appropriate control amounts (flow rates) for each of the flow rate adjustment units 71A, 72A, 71B, and 72B can be obtained in advance by an experiment or the like, and the control amount of each of the flow rate adjustment units 71A, 72A, 71B, and 72B based on such an experimental result can be stored in the storage device of the control unit 200. The flow rate control unit 202 controls each of the flow rate adjustment units 71A, 72A, 71B, and 72B based on the control amounts stored in the storage device.

By controlling the flow rate ratio of the helium gas and the argon gas for each of the first mixed gas and the second mixed gas in this manner, it is possible to increase the thermal conductivity for the backside gas at the outer peripheral portion of the semiconductor substrate W more than the thermal conductivity for the backside gas at the central portion of the semiconductor substrate W. In other words, since the outer peripheral portion of the semiconductor substrate W can be cooled more than the central portion of the semiconductor substrate W, the temperature distribution of the semiconductor substrate W can be made more uniform.

In addition, when a temperature difference of approximately 30° C. is generated between the central portion and the outer peripheral portion of the semiconductor substrate W, the flow rate control unit 202 controls the flow rate adjustment units 71B and 72B such that the flow rate of each of the helium gas and the argon gas contained in the second mixed gas is 8:2 (helium gas flow rate:argon gas flow rate). In other words, the larger the temperature difference between the central portion and the outer peripheral portion of the semiconductor substrate W, the larger the flow rate of the helium gas contained in the second mixed gas. Accordingly, since the thermal conductivity for the backside gas at the outer peripheral portion of the semiconductor substrate W can be increased and the outer peripheral portion of the semiconductor substrate W can be further cooled, the temperature distribution of the semiconductor substrate W can be made more uniform.

The plasma treatment apparatus 10 of this third embodiment includes the first gas supply unit 70A that supplies the first mixed gas to the central portion of the semiconductor substrate W and the second gas supply unit 70B that supplies the second mixed gas at the outer portion of the central portion of the semiconductor substrate W. The second mixed gas more helium gas to have a higher thermal conductivity than that of the first mixed gas. According to this configuration, the second mixed gas (having higher thermal conductivity) is supplied to the outer portion of the semiconductor substrate W where the temperature tends to be higher. Thus, the temperature of the semiconductor substrate W can be made more uniform.

The flow rate control unit 202 controls the first flow rate adjustment units 71A and 72A and the second flow rate adjustment units 71B and 72B such that the pressures of each of the first mixed gas and the second mixed gas become the same predetermined pressure. As in this configuration, when the pressures of each of the first mixed gas and the second mixed gas are controlled to the same predetermined pressure, the parameter that primarily affects the temperature of the semiconductor substrate W is the flow rate ratio of each of the helium gas and the argon gas contained in the mixed gas, and thus the temperature control of the semiconductor substrate W becomes simpler.

### First Modification Example

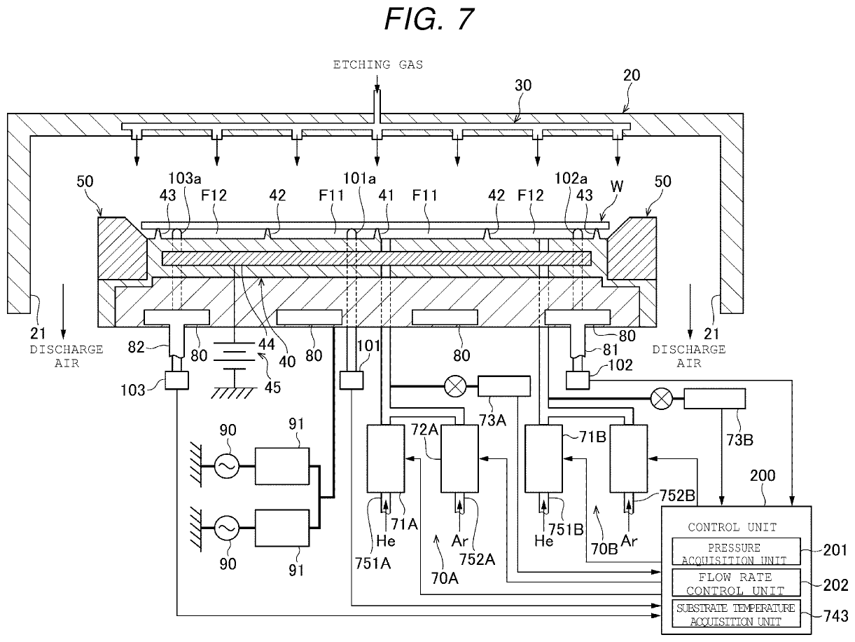

As shown in FIG. 7, the plasma treatment apparatus 10 of this modification example further includes substrate temperature sensors 101 to 103. The substrate temperature sensor 101 has a probe 101a which is in contact with the central portion of the semiconductor substrate W, and directly measures the temperature of the central portion of the semiconductor substrate W via the probe 101a. The substrate temperature sensors 102 and 103 each have probes 102a and 103a which are in contact with the outer peripheral portion of the semiconductor substrate W, and directly measure the temperature of the outer peripheral portion of the semiconductor substrate W via the probes 102a and 103a. The substrate temperature sensors 101 to 103 output a signal corresponding to the measured temperature to the control unit 200.

The control unit 200 further includes a substrate temperature acquisition unit 204 as a functional aspect implemented by the CPU executing a program stored in the storage device. The substrate temperature acquisition unit 204 acquires a temperature Ta of the central portion and a temperature Tb of the outer peripheral portion of the semiconductor substrate W based on the output signals of the substrate temperature sensors 101 to 103.

The flow rate control unit 202 controls the flow rate adjustment units 71A, 72A, 71B, and 72B of the gas supply units 70A and 70B based on the temperature Ta of the central portion and the temperature Tb of the outer peripheral portion of the semiconductor substrate W, which are acquired by the substrate temperature acquisition unit 204. For example, the flow rate control unit 202 calculates the deviation between the temperature Ta of the central portion of the semiconductor substrate W and a predetermined target temperature T*, and controls the flow rate adjustment units 71A and 72A of the first gas supply unit 70A such that the flow rate of the helium gas contained in the first mixed gas increases and the flow rate of the argon gas decreases as the calculated temperature deviation ΔTa (increases (ΔTa=Ta−T*). In addition, the flow rate control unit 202 calculates the deviation between the temperature Tb of the outer peripheral portion of the semiconductor substrate W and a predetermined target temperature T*, and controls the flow rate adjustment units 71B and 72B of the second gas supply unit 70B such that the flow rate of the helium gas contained in the second mixed gas increases and the flow rate of the argon gas decreases as the calculated temperature deviation ΔTb increases (ΔTb=Tb−T*).

In this manner, the flow rate control unit 202 of this modification example controls the first flow rate adjustment units 71A and 72A and the second flow rate adjustment units 71B and 72B based on the measured temperatures Ta and Tb of the semiconductor substrate W. According to this configuration, two types of gases contained in each of the first mixed gas and the second mixed gas are independent adjusted based on the measured temperatures Ta and Tb of the semiconductor substrate W. In other words, since the thermal conductivity of each of the first mixed gas and the second mixed gas can be separately adjusted, it becomes easier to make the temperature of the semiconductor substrate W more uniform.

### Second Modification Example

The plasma treatment apparatus 10 of this modification example estimates the temperature of the semiconductor substrate W based on the temperature of the refrigerant, and then controls the flow rate adjustment units 71A, 72A, 71B, and 72B based on this estimated temperature of the semiconductor substrate W.

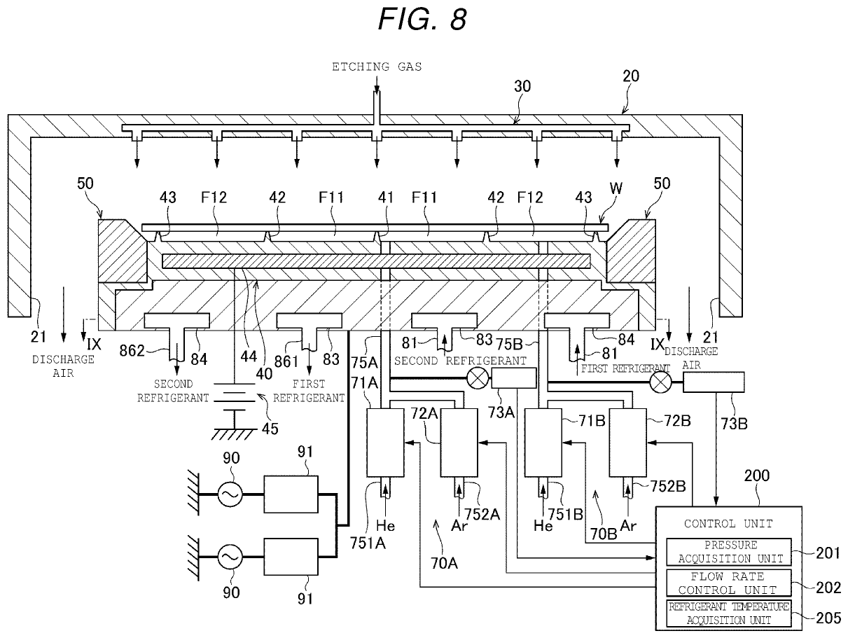

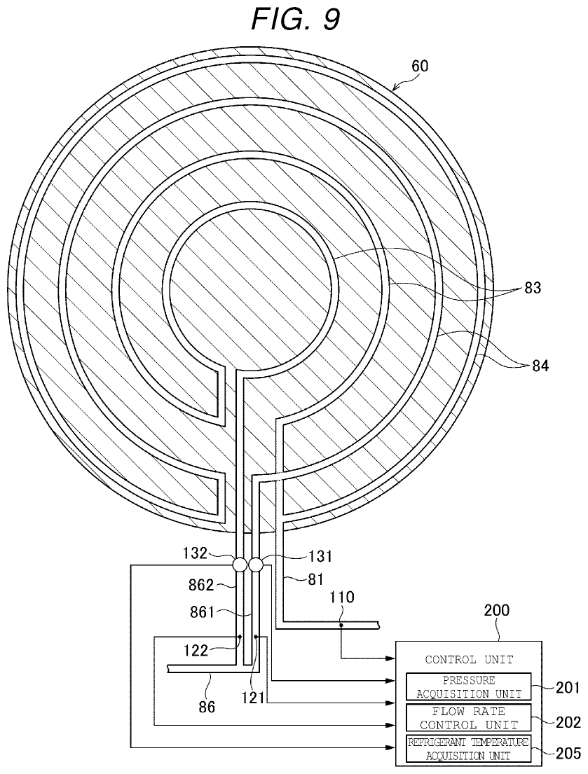

Specifically, as shown in FIG. 8, the refrigerant flow paths 83 and 84, which are independent of each other, are formed inside the substrate holder 40. FIG. 9 shows the cross-sectional structure of the substrate holder 40 along line IX-IX of FIG. 8. As shown in FIG. 9, the first refrigerant flow path 83 extends in a double circular shape at the central portion of the substrate holder 40. The second refrigerant flow path 84 extends in a double circular shape at the outer peripheral portion of the substrate holder 40.

As shown in FIG. 8, the first refrigerant flow path 83 is disposed at a position corresponding to the first gas supply space F11. The second refrigerant flow path 84 is disposed at a position corresponding to the second gas supply space F12. Hereinafter, the refrigerant flowing through the first refrigerant flow path 83 is also referred to as a “first refrigerant”, and the refrigerant flowing through the second refrigerant flow path 84 is also referred to as a “second refrigerant”.

As shown in FIG. 9, the upstream part of the first refrigerant flow path 83 and the second refrigerant flow path 84 is connected to the common inflow path 81. Therefore, the refrigerant having the same temperature flows into the first refrigerant flow path 83 and the second refrigerant flow path 84 from the inflow path 81. The inflow path 81 is provided with a temperature sensor 110 that measures a temperature TO of the refrigerant flowing through the inflow path 81. The temperature sensor 110 outputs a signal corresponding to the measured temperature TO of the refrigerant to the control unit 200.

The downstream part of the first refrigerant flow path 83 and the second refrigerant flow path 84 is connected to each of branch flow paths 861 and 862. The downstream part of the branch flow paths 861 and 862 is connected to a common outflow path 86. Therefore, the refrigerant that flowed through each of the first refrigerant flow path 83 and the second refrigerant flow path 84 flows to the outflow path 86 via the branch flow paths 861 and 862. The branch flow paths 861 and 862 are provided with temperature sensors 121 and 122 and flow velocity sensors 131 and 132, respectively. The temperature sensors 121 and 122 measure the temperatures T1 and T2 of the refrigerant flowing through the branch flow paths 861 and 862, respectively, and output signals corresponding to the measured temperatures T1 and T2 to the control unit 200, respectively. The flow velocity sensors 131 and 132 measure the flow velocities V1 and V2 of the refrigerant flowing through the branch flow paths 861 and 862, respectively, and output signals corresponding to the measured flow velocities V1 and V2 to the control unit 200, respectively.

The control unit 200 further includes a refrigerant temperature acquisition unit 205 as a functional aspect implemented by the CPU executing a program stored in the storage device. The refrigerant temperature acquisition unit 205 acquires the pre-passage temperature T0 (temperature of the refrigerant before passing through the first refrigerant flow path 83 and the second refrigerant flow path 84) based on the output signal of the temperature sensor 110. The refrigerant temperature acquisition unit 205 also acquires the first post-passage temperature T1 (temperature of the refrigerant after passing through the first refrigerant flow path 83) and the second post-passage temperature T2 (temperature of the refrigerant after passing through the second refrigerant flow path 84) based on the output signals of the temperature sensors 121 and 122.

The flow rate control unit 202 of the control unit 200 controls the flow rate adjustment units 71A, 72A, 71B, and 72B based on the pre-passage temperature T0, the first post-passage temperature T1, and the second post-passage temperature T2, which are acquired by the refrigerant temperature acquisition unit 205, and the flow velocities V1 and V2 of the refrigerant measured by the flow velocity sensors 131 and 132.

For example, the flow rate control unit 202 calculates a first temperature change amount ΔT1, which is a temperature change amount per unit time of the first refrigerant flowing through the first refrigerant flow path 83, based on the following Equation f1 from the pre-passage temperature T0 and the first post-passage temperature T1 and the flow velocity V1. In the following Equation f1, “L1” is the flow path length of the first refrigerant flow path 83.

ΔT1=(T1−T0)×V1/L1 (Equation f1)

Further, the flow rate control unit 202 calculates a second temperature change amount ΔT2, which is the temperature change amount per unit time of the second refrigerant flowing through the second refrigerant flow path 84, based on the following Equation f2. In the following Equation f2, “L2” is the flow path length of the second refrigerant flow path 84.

ΔT2=(T2−T0)×V2/L2 (Equation f2)

The first refrigerant flowing through the first refrigerant flow path 83 primarily absorbs the heat of the central portion of the semiconductor substrate W transferred via the first mixed gas in the first gas supply space F11. Therefore, the first temperature change amount ΔT1 calculated by the above Equation f1 has a correlation to the temperature of the central portion of the semiconductor substrate W. Similarly, the second temperature change amount ΔT2 calculated by the above Equation f2 has a correlation to the temperature of the outer peripheral portion of the semiconductor substrate W.

Using this, the flow rate control unit 202 of the control unit 200 controls the flow rate adjustment units 71A and 72A of the first gas supply unit 70A such that the first temperature change amount ΔT1 becomes a predetermined value. Similarly, the flow rate control unit 202 controls the flow rate adjustment units 71B and 72B of the second gas supply unit 70B such that the second temperature change amount ΔT2 becomes a predetermined value.

According to the plasma treatment apparatus 10 of this modification example, the first temperature change amount ΔT1 and the second temperature change amount ΔT2 are controlled to the same predetermined value, and as a result, it becomes easier to match the temperature of the central portion with the temperature of the outer peripheral portion of the semiconductor substrate W. Therefore, it becomes easier to make the temperature of the semiconductor substrate W more uniform.

The flow rate control unit 202 may control the flow rate adjustment units 71A and 72A of the first gas supply unit 70A and the flow rate adjustment units 71B and 72B of the second gas supply unit 70B such that the first temperature change amount ΔT1 and the second temperature change amount ΔT2 are in a predetermined ratio. Even with such a configuration, it is possible to obtain the same or similar actions and effects.

### Other Embodiments

The present disclosure is not specifically limited to the above.

For example, the mixed gas supplied to the substrate holder 40 and the semiconductor substrate W is not limited to a mixed gas containing two types of gases, nor particularly helium gas and argon gas. For example, a mixed gas in which three or more gases having different thermal conductivities are mixed may be used.

In the plasma treatment apparatus 10 of each embodiment, the pressure of the mixed gas may be changed or varied as another means of controlling temperature. For example, in the plasma treatment apparatus 10 of the second embodiment, the pressure of the first mixed gas and the pressure of the second mixed gas may be different from one another.

### Example of Method for Manufacturing Semiconductor Device

Hereinafter, an example of a method for manufacturing a semiconductor device using the plasma treatment methods of the first to third embodiments will be described. The semiconductor device of this example is a three-dimensional NAND flash memory.

In manufacturing a semiconductor device, for example, the plasma treatment methods of the first to third embodiments may be used in the process of forming a memory hole in a film stack. A semiconductor device is manufactured through a process or the like in which a memory hole is etched into a film stack in which an insulating layer containing silicon oxide and a sacrificial layer containing silicon nitride are alternately stacked for several layers. A memory film or a semiconductor channel is subsequently embedded in the etched memory hole.

According to the plasma treatment methods of the first to third embodiments, it is possible to suitably control the temperature of the semiconductor substrate. For example, when forming a memory hole having a high aspect ratio through the film stack, it is desirable to perform low-temperature etching in order to process the stack at high speed. However, high-speed low-temperature etching may not be able to partially obtain a desired shape for the memory hole. For example, the size of the bottom of the memory hole becoming smaller than intended or smaller than an upper portion of the memory hole. In this case, it is possible to make adjustments such as increasing the size of the bottom of the memory hole by performing high-temperature (room-temperature) etching. Further, by switching between low-temperature etching and room-temperature etching at a desired timing, the roundness of the memory hole can be increased. Accordingly, it becomes possible to manufacture high-quality semiconductor devices.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A plasma treatment apparatus, comprising:
a holding unit configured to hold a substrate during a plasma treatment process;
a gas supply unit configured to supply a mixed gas, including a first gas and a second gas, to a gas supply space formed between the substrate and the holding unit;
a flow rate adjustment unit configured to change a flow rate of each of the first and second gases; and
a flow rate control unit configured to control the flow rate adjustment unit during the plasma treatment process to change a relative flow rate of the first and second gases to control a temperature of the substrate between a first relative flow rate in which the flow rate of the first gas is larger than the flow rate of the second gas and a second relative flow rate in which the flow rate of the second gas is larger than the flow rate of the first gas.

2. The plasma treatment apparatus according to claim 1, further comprising:
a refrigerant temperature changing unit configured to change a temperature of a refrigerant supplied to the holding unit.

3. The plasma treatment apparatus according to claim 1, further comprising:
a refrigerant supply unit configured to supply a first refrigerant flow at a first temperature and a second refrigerant flow at a second temperature to the holding unit; and
a switching unit configured to individually adjust a flow rate of the first refrigerant flow and a flow rate of the second refrigerant flow of refrigerants to the holding unit.

4. The plasma treatment apparatus according to claim 1, wherein the holding unit is an electrostatic chuck.

5. The plasma treatment apparatus according to claim 4, wherein
the electrostatic chuck includes a plurality of support units contacting a backside of the substrate during the plasma treatment,
the gas supply space is partitioned into different regions by the plurality of support units, and
the gas supply unit is configured to separately supply the mixed gas to each region of the gas supply space.

6. The plasma treatment apparatus according to claim 1, wherein the gas supply unit comprises:
a first branch connected to a first gas supply,
a second branch connected to a second gas supply, and
a mixed gas path passing through the holding unit to the gas supply space from a joining point of the first and second branches.

7. The plasma treatment apparatus according to claim 1, further comprising:
a pressure sensor to measure a pressure in the gas supply region, wherein
the flow rate control unit is further configured to control the flow rate adjustment unit to maintain a constant pressure in the gas supply region.

8. The plasma treatment apparatus according to claim 1, wherein the flow rate control unit is a processor.

9. The plasma treatment apparatus according to claim 1, further comprising:
a plasma chamber enclosing the holding unit; and
a showerhead configured to supply plasma process gas to the plasma chamber from above the holding unit.

10. A plasma treatment apparatus, the apparatus comprising:
a holding unit configured to hold a substrate during a plasma processing, the holding unit including supporting partitions on a surface facing a backside of the substrate, the supporting partitions partitioning a gap region formed between the backside of the substrate and the holding unit into a plurality of independent gas supply spaces; and
a plurality of gas supply units configured to separately supply gas to each of the independent gas supply spaces, wherein
at least one of the plurality of gas supply units supplies a mixed gas to the corresponding independent gas supply space.

11. The plasma treatment apparatus according to claim 10, wherein the plurality of independent gas supply units includes:
a first gas supply unit that supplies a first mixed gas to a central independent gas supply space corresponding in position to a central portion of the substrate, and
a second gas supply unit that supplies a second mixed gas to a peripheral independent gas supply space corresponding in position to an outer peripheral portion of the substrate outside the central portion.

12. The plasma treatment apparatus according to claim 11, wherein the first and second mixed gases have different ratios of a first gas to a second gas.

13. The plasma treatment apparatus according to claim 11, further comprising:
a refrigerant temperature acquisition unit to acquire a temperature of a refrigerant supplied to the holding unit;
a first flow rate adjustment unit that adjusts a flow rate of gases in the first mixed gas;
a second flow rate adjustment unit that adjusts a flow rate of gases in the second mixed gas; and
a flow rate control unit configured to control the first flow rate adjustment unit and the second flow rate adjustment unit based on the acquired temperature of the refrigerant.

14. The plasma treatment apparatus according to claim 13, wherein
a first refrigerant flow path for a first refrigerant is provided inside the holding unit to correspond to a position of the central portion of the substrate, and
a second refrigerant flow path for a second refrigerant is provided inside the holding unit to correspond to a position of the outer peripheral portion of the substrate.

15. The plasma treatment apparatus according to claim 14, wherein
the refrigerant temperature acquisition unit acquires:
a pre-passage temperature for the first refrigerant flow path and the second refrigerant flow path,
a post-passage temperature for the first refrigerant flow path, and
a post-passage temperature for the second refrigerant flow path; and
the flow rate control unit:
calculates a first temperature change value, which is a temperature change amount per unit time for the first refrigerant based on a difference between the pre-passage temperature and the first post-passage temperature for the first refrigerant,
calculates a second temperature change value, which is a temperature change amount per unit time of the second refrigerant based on a difference between the pre-passage temperature and the second post-passage temperature for the second refrigerant, and
controls the first flow rate adjustment unit and the second flow rate adjustment unit such that the first temperature change value and the second temperature change value each become a predetermined value.

16. The plasma treatment apparatus according to claim 13, wherein the flow rate control unit controls the first flow rate adjustment unit and the second flow rate adjustment unit such that pressures of the first mixed gas and the second mixed gas are a substantially constant value.

17. The plasma treatment apparatus according to claim 11, further comprising:
a substrate temperature acquisition unit that acquires a temperature of the substrate;
a first flow rate adjustment unit that adjusts a flow rate of each gas contained in the first mixed gas;
a second flow rate adjustment unit that adjusts a flow rate of each gas contained in the second mixed gas; and
a flow rate control unit that controls the first flow rate adjustment unit and the second flow rate adjustment unit based on the acquired temperature of the substrate.

18. A plasma treatment method for treating a substrate in a plasma atmosphere, the method comprising:
holding a substrate with a holding unit that is configured to hold the substrate during a plasma treatment process;
supplying a mixed gas, including a first gas and a second gas, to a gas supply space formed between the substrate and the holding unit; and
changing a flow rate of each of the first and second gases to change a relative flow rate of the first and second gases to control a temperature of the substrate.

19. The plasma treatment method according to claim 18, further comprising:
changing a temperature of a refrigerant supplied to the holding unit.

20. The plasma treatment method according to claim 18, wherein the substrate is a semiconductor substrate.
